(19) United States
(12) Patent Application Publication
(10) Pub. No.: US 2023/0014710 A1
(43) Pub. Date: Jan. 19, 2023

(54) MOUNTING BRACKET FOR BUSHING WELL INTERUPTER CONTROLS

(71) Applicant: S&C Electric Company, Chicago, IL (US)

(72) Inventors: Thomas S. Kelley, Highland Park, IL (US); Thomas J. Dyer, Minneola, FL (US); Joseph W. Milton, Milwaukee, WI (US); David G. Porter, East Troy, WI (US)

(73) Assignee: S&C Electric Company, Chicago, IL (US)

(21) Appl. No.: 17/715,375

(22) Filed: Apr. 7, 2022

Related U.S. Application Data
(60) Provisional application No. 63/220,291, filed on Jul. 9, 2021.

(51) Int. Cl. H05K 7/14; F16M 13/02

(52) U.S. Cl. CPC H05K 7/1417; F16M 13/02

(57) ABSTRACT

A mounting bracket for securing a control unit that controls a bushing well interrupter device provided within a transformer enclosure associated with an underground loop circuit. The mounting bracket includes a support portion configured to hold the control unit and a mounting portion coupled to the mounting portion, where the mounting portion including a hook portion configured to hook onto one terminal in the enclosure and a notch portion configured to rest against another terminal in the enclosure.

### CROSS-REFERENCE TO RELATED APPLICATION

This application claims the benefit of priority from the United States Provisional Application No. 63/220,291, filed on Jul. 9, 2021, the disclosure of which is hereby expressly incorporated herein by reference for all purposes.

### BACKGROUND

### Field

The present disclosure relates generally to a mounting bracket for securing a control unit that controls a bushing well interrupter device provided within a transformer enclosure.

### Discussion of the Related Art

An electrical power distribution network, often referred to as an electrical grid, typically includes a number of power generation plants each having a number of power generators, such as gas turbines, nuclear reactors, coal-fired generators, hydro-electric dams, etc. The power plants provide power at a variety of medium voltages that are then stepped up by transformers to a high voltage AC signal to be connected to high voltage transmission lines that deliver electrical power to a number of substations typically located within a community, where the voltage is stepped down to a medium voltage for distribution. The substations provide the medium voltage power to a number of three-phase feeders including three single-phase feeder lines that carry the same current, but are 120^{o} apart in phase. A number of three-phase and single phase lateral lines are tapped off of the feeder that provide the medium voltage to various distribution transformers, where the voltage is stepped down to a low voltage and is provided to a number of loads, such as homes, businesses, etc.

Periodically, faults occur in the distribution network as a result of various things, such as animals touching the lines, lightning strikes, tree branches falling on the lines, vehicle collisions with utility poles, etc. Faults may create a short-circuit that increases the load on the network, which may cause the current flow from the substation to significantly increase, for example, many times above the normal current, along the fault path. This amount of current causes the electrical lines to significantly heat up and possibly melt, and also could cause mechanical damage to various components in the substation and in the network. Power distribution networks of the type referred to above often include a number of switching devices, breakers, reclosers, interrupters, etc. that control the flow of power throughout the network, and may be used to isolate faults within a faulted section of the network.

As part of their power distribution network, many utility companies employ a number of underground single-phase lateral circuits that feed residential and commercial customers. Often times these circuits are configured in a loop and fed from both ends, where an open location, typically at a transformer, is used in the circuit to isolate the two power sources. Although providing underground power cables protects circuits from faults created by things like storms and vegetation growth, underground cables still may break or otherwise be disrupted as a result of corrosion and other things.

For a residential loop circuit of the type referred to above having two power sources, it is usually possible to reconfigure the open location in the circuit so that loads that are affected by a disrupted cable are fed by the other source and service to all of the loads is maintained. However, known processes for identifying the location of a cable disruption and the subsequent reconfiguration of the open location often result in long power restoration times because workers are required to physically go to the transformers to test for power and then reconfigure the transformers to change the open location. It has been proposed to provide bushing well interrupter devices in the existing transformers for these types of loop circuits that provide automatic protection, isolation and restoration of underground residential cable loops and methods to switch cable segments without handling cable elbows.

### SUMMARY

The following discussion discloses and describes a mounting bracket for securing a control unit that controls a bushing well interrupter device provided within a transformer enclosure associated with an underground loop circuit. The mounting bracket includes a support portion configured to hold the control unit and a mounting portion coupled to the support portion, where the mounting portion includes a hook portion configured to hook onto one terminal in the enclosure and a notch portion configured to rest against another terminal in the enclosure.

Additional features of the disclosure will become apparent from the following description and appended claims, taken in conjunction with the accompanying drawings.

### BRIEF DESCRIPTION OF THE DRAWINGS

FIG. 1 is an isometric view of a pad mounted transformer employed in an underground residential loop circuit;

FIG. 2 is a front view of the transformer shown in FIG. 1;

FIGS. 3-6 are isometric views at various angles of a control unit assembly separated from the transformer shown in FIGS. 1 and 2 and including a control unit and a mounting bracket;

FIG. 7 is a cut-away isometric view of the pad mounted transformer including a different type of control unit assembly having a mounting bracket for a control unit; and

FIG. 8 is a back isometric view of the control unit assembly shown in FIG. 7 separated from the transformer.

### DETAILED DESCRIPTION OF THE EMBODIMENTS

The following discussion of the embodiments of the disclosure directed to a mounting bracket for securing a control unit that controls a bushing well interrupter device provided within a transformer enclosure is merely exemplary in nature, and is in no way intended to limit the invention or its applications or uses. For example, the mounting brackets discussed herein have particular application for use with transformers employed in underground residential loop circuits. However, the mounting brackets may have other applications.

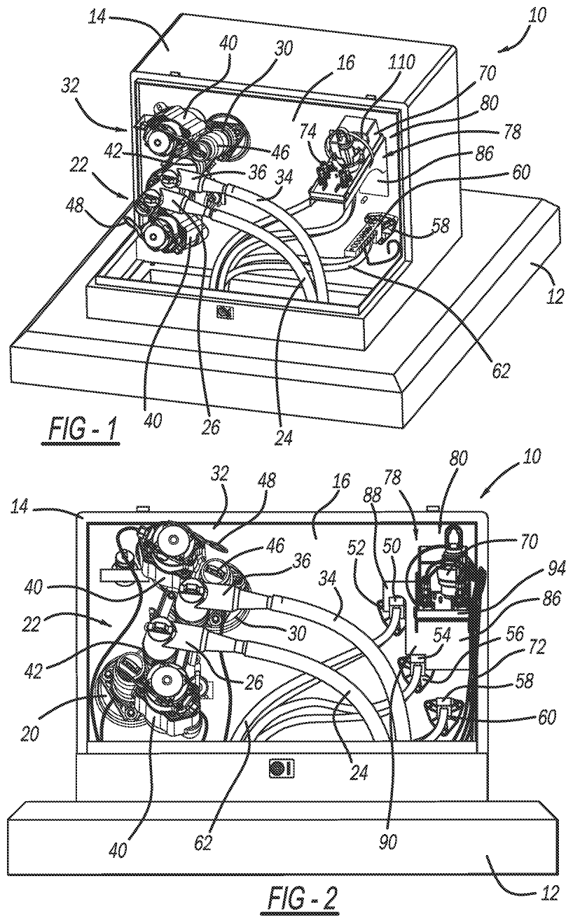

FIG. 1 is an isometric view and FIG. 2 is a front view of a transformer 10 of the type that is mounted on a pad 12 that may be employed in an underground single-phase lateral loop circuit that feeds residential and commercial customers. The transformer 10 includes an enclosure 14 that houses the transformer primary and secondary coils (not shown) and other electrical components (not shown) of the transformer 10. A cover of the enclosure 14 has been removed to expose a panel 16 in the enclosure 14. A connector bushing 20 extends through the panel 16 that accepts a bushing well interrupter device 22 that connects a power line 24 having an elbow connector 26 to one side of the primary coil and a connector bushing 30 extends through the panel 16 that accepts a bushing well interrupter device 32 that connects a power line 34 having an elbow connector 36 to the other side of the primary coil, where the bushing well interrupter devices 22 and 32 are configured to provide automatic protection, isolation and power restoration of a lateral loop circuit without handling cable elbows. The devices 22 and 32 each include an outer enclosure 40, a load-break interface 42, a transformer interface 46 and a manual handle 48. A 120 V positive connector 50 is coupled to the secondary coil through a bushing 52 in the panel 16, a 120 V negative connector 54 is coupled to the secondary coil through a bushing 56 in the panel 16, and a neutral connector 58 is coupled to the secondary coil through a bushing 60 in the panel 16. Distribution lines 62 are connected to the connectors 50, 54 and 58 to deliver low voltage power to the desired number of loads (not shown). In this example, the lines 24, 34 and 62 run underground.

The bushing well interrupter devices 22 and 32 are an added feature to existing transformers of the type shown and described above already operating in the field, and are configured to be usable in the space provided in the enclosure 14. This configuration includes controlling the devices 22 and 32 by a common control unit 70, where the control unit 70 is powered by 120 V ac from the secondary coil and is connected to the bushing well interrupter devices 22 and 32 by control lines 72 connected to terminals 74 on the control unit 70. In order to allow the devices 22 and 32 to be employed in existing pad mounted transformers of the type described herein, the control unit 70 needs to be easily mounted to the existing structure. This disclosure proposes a mounting bracket 78 that is hung from the connector 50 adjacent to the bushing 52 for this purpose, where the distance between and the location of the bushings 52 and 56 in all of the transformers of this type are set by industry standards. The mounting bracket 78 is made of an electrically insulating material, such as a suitable plastic, to provide electrical isolation between the connectors 50, 54 and 58 and the control unit 70.

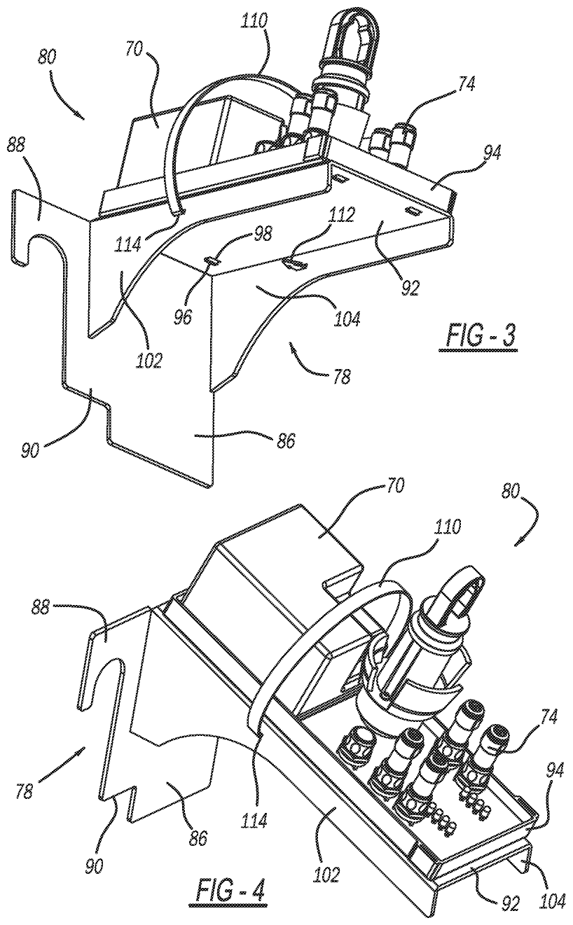

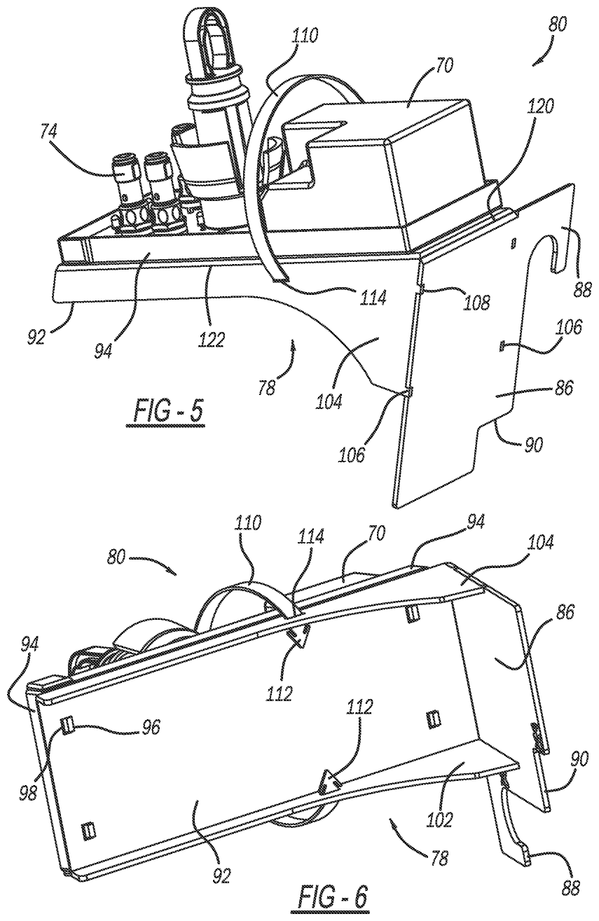

FIGS. 3-6 are isometric views at various angles of a control unit assembly 80 separated from the transformer 10 and including the control unit 70 and the mounting bracket 78. The bracket 78 includes a mounting portion 86 having a hook portion 88 and a notch portion 90 that are sized and spaced apart so that the hook portion 88 can be hooked on the connector 50 and the notch portion 90 can rest against the connector 54 to support the assembly 80. A support portion 92 is coupled to and extends downward from the mounting portion 86. The control unit 70 includes a base plate 94 having snap tabs 96 that snap into slots 98 in the support portion 92 to provide tool-less installation of the control unit 70. In this non-limiting embodiment, the support portion 92 is at a 30° angle relative to the mounting portion 86 to provide greater visibility of the control unit 70. The support portion 92 includes side rails 102 and 104 having tabs 106 that are inserted into slots 108 in the mounting portion 86. A flexible strap 110 is secured to the bracket 78 by inserting hooked ends 112 of the strap 110 into slots 114 in the side rails 102 and 104, where the strap 110 operates as a handle for allowing a worker to grab the assembly 80 with a shotgun stick to remove it from the enclosure 14 or place it in the enclosure 14. In one embodiment, the bracket 78 is assembled from a flat piece of plastic having the proper scoring and slots to be formed as shown, where live hinges 120 and 122 are provided between the portions 86 and 92 and the support portion 92 and the side rails 102 and 104.

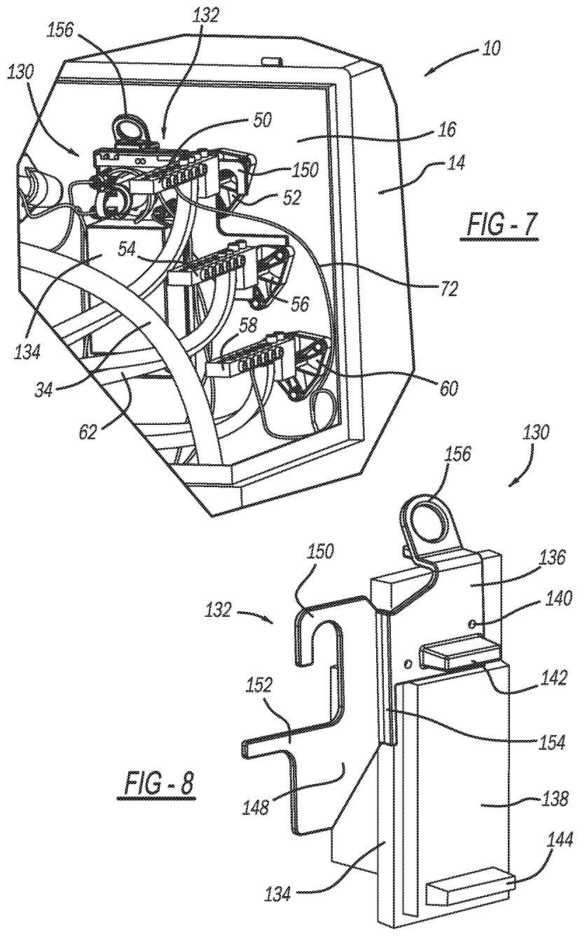

The bracket 78 offers one configuration of a device for mounting a control unit to the existing structure of the transformer 10. Other configurations may be equally applicable. FIG. 7 is a cut-away isometric view of the transformer 10 including another style and design of a mounting assembly 130 including a mounting bracket 132 and a control unit 134, where the bracket 132 also hangs on the connector 50. FIG. 8 is a back isometric view of the mounting assembly 130 separated from the transformer 10. The bracket 132 includes a support portion 136 secured to a back panel 138 of the control unit 134 by screws 140. A stand-off 142 extends from the support portion 136 and a stand-off 144 extends from the back panel 138 of the control unit 134 that rest against the panel 16. The bracket 132 also includes a mounting portion 148 having a hook portion 150 that hooks on the connector 50 and a notch portion 152 that rests against the connector 54, where the mounting portion 148 is offset from the support portion 136 by a ridge portion 154. An eyehole 156 extends up from the support portion 136 to allow the assembly 130 to be hung on and removed from the connector 50 using a shotgun stick.

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

What is claimed is:

1. A mounting bracket for securing a control unit to a transformer enclosure, the bracket comprising:
a support portion configured to hold the control unit; and
a mounting portion coupled to the support portion, the mounting portion including a hook portion configured to hook onto one terminal in the enclosure and a notch portion configured to rest against another terminal in the enclosure.

2. The mounting bracket according to claim 1 further comprising a grasping portion coupled to and extending from the support portion.

3. The mounting bracket according to claim 2 wherein the grasping portion is a strap.

4. The mounting bracket according to claim 2 wherein the grasping portion is an eyehole.

5. The mounting bracket according to claim 1 wherein the mounting portion is coupled to the support portion by a live hinge.

6. The mounting bracket according to claim 1 wherein the mounting portion is coupled to the support portion by tabs extending from the support portion inserted into slots in the mounting portion.

7. The mounting bracket according to claim 1 wherein the support portion holds the control unit by tabs extending from the control unit inserted into slots in the support portion.

8. The mounting bracket according to claim 1 wherein the support portion includes opposing side rails coupled to the mounting portion.

9. The mounting bracket according to claim 1 wherein the mounting portion is offset from the support portion by a ridge portion.

10. The mounting bracket according to claim 1 wherein the support portion is coupled to the mounting portion at an angle of about 30°.

11. The mounting bracket according to claim 1 wherein the mounting bracket is plastic.

12. The mounting bracket according to claim 11 wherein the mounting bracket is formed from a scored sheet of plastic.

13. The mounting bracket according to claim 1 wherein the terminals are 120 V terminals.

14. The mounting bracket according to claim 1 wherein the transformer is part of an underground residential loop circuit.

15. The mounting bracket according to claim 1 wherein the control unit controls a bushing well interrupter device.

16. A plastic mounting bracket for securing a control unit to a transformer enclosure, the bracket comprising:
a support portion configured to hold the control unit, the support portion including a bottom plate on which the control unit sits and opposing side rails; and
a mounting portion coupled to the support portion by tabs extending from ends of the rails being inserted into slots in the mounting portion, the mounting portion including a hook portion configured to hook onto one terminal in the enclosure and a notch portion configured to rest against another terminal in the enclosure.

17. The mounting bracket according to claim 16 wherein the support portion is coupled to the mounting portion at an angle of about 30°.

18. The mounting bracket according to claim 16 wherein the support portion is further coupled to the mounting portion by a live hinge.

19. The mounting bracket according to claim 16 further comprising a grasping strap coupled to and extending from the support portion.

20. A plastic mounting bracket for securing a control unit to a transformer enclosure, the bracket comprising:
a support portion configured to hold the control unit; and
a mounting portion coupled to the support portion by a ride portion so that the mounting portion is offset from the support portion, the mounting portion including a hook portion configured to hook onto one terminal in the enclosure and a notch portion configured to rest against another terminal in the enclosure.
